(19) United States
(12) Patent Application Publication
(10) Pub. No.: US 2004/0037972 A1
(43) Pub. Date: Feb. 26, 2004

(54) Patterned granulized catalyst layer suitable for electron-emitting device, and associated fabrication method

(76) Inventors: Kang Simon, San Jose, CA (US); Bae Craig, San Jose, CA (US); Kim Jung Jae, San Jose, CA (US)

Correspondence Address: CDREAM DISPLAY CORPORATION, 6910 Santa Teresa Blvd., San Jose, CA, 95119, US

(21) Appl. No.: 10/226,873

(22) Filed: Aug. 22, 2002

(51) Int. Cl. C23C 16/26

(52) U.S. Cl. 427/575; 427/577; 427/249.1; 427/255.11

(57) ABSTRACT

An electron-emitting device contains a vertical emitter electrode patterned into multiple laterally separated sections situated between the electron-emissive elements, on one hand, and a substrate, on the other hand. The electron-emissive elements comprising carbon nanotubes are grown at a temperature range of 200° C. to 600° C. compatible with the thermal stress of the underlying substrate. The electron-emissive elements are grown on a granulized catalyst layer that provides a large surface area for growing the electron-emissive elements at such low temperature ranges.

### FIELD OF USE

This invention relates to carbon nano tube based field emitters. More particularly, this invention relates to the structure and fabrication of an electron-emitting device in which electrically conductive material is situated between electron-emissive elements, on one hand, and emitter electrodes, on the other hand, and which is suitable for use in a flat-panel display of the cathode-ray tube (“CRT”) type.

### BACKGROUND

A Cathode Ray Tube (CRT) display generally provides the best brightness, highest contrast, best color quality and largest viewing angle of prior art computer displays. CRT displays typically use a layer of phosphor which is deposited on a thin glass faceplate. These CRTs generate a picture by using one to three electron beams which generate high energy electrons that are scanned across the phosphor in a raster pattern. The phosphor converts the electron energy into visible light so as to form the desired picture. However, prior art CRT displays are large and bulky due to the large vacuum envelopes that enclose the cathode and extend from the cathode to the faceplate of the display. Therefore, typically, other types of display technologies such as active matrix liquid crystal display, plasma display and electroluminescent display technologies have been used in the past to form thin displays.

Recently, a thin flat panel display (FPD) has been developed which uses the same process for generating pictures as is used in CRT devices. These flat panel displays use a backplate including a matrix structure of rows and columns of electrodes. One such flat panel display is described in U.S. Pat. No. 5,541,473 which is incorporated herein by reference. Flat panel displays are typically matrix-addressed and they comprise matrix addressing electrodes. The intersection of each row line and each column line in the matrix defines a pixel, the smallest addressable element in an electronic display.

The essence of electronic displays is the ability to turn on and off individually picture elements (pixels) A typical high information content display will have about a quarter million pixels in a 33 cm diagonal orthogonal array, each under individual control by the electronics. The pixel resolution is normally just at or below the resolving power of the eye. Thus, a good quality picture can be created from a pattern of activated pixels.

One means for generating arrays of field emission cathode structures relies on well established semiconductor micro-fabrication techniques. These techniques produce highly regular arrays of precisely shaped field emission tips. Lithography, generally used in these techniques, involves numerous processing steps, many of them wet. The number of tips per unit area, the size of the tips, and their spacing are determined by the available photo-resist and the exposing radiation.

Tips produced by the method are typically cone-shaped with base diameters on the order of 0.5 to 1 um, heights of anywhere from 0.5 to 2 um, tip radii of tens of nanometers. This size limits the number of tips per pixel possible for high resolution displays, where large numbers (400-1000 emitters per pixel) are desirable for uniform emission to provide adequate gray levels, and to reduce the current density per tip for stability and long lifetimes. Maintaining two dimensional registry of the periodic tip arrays over large areas, such as large TV-sized screens, can also be a problem for gated field emission constructions by conventional means, resulting in poor yields and high costs.

U.S. Pat. No. 4,338,164 describes a method of preparing planar surfaces having a micro-structured protuberances thereon comprising a complicated series of steps involving irradiation of a soluble matrix (e.g., mica) with high energy ions, as from a heavy ion accelerator, to provide column-like traces in the matrix that are subsequently etched away to be later filled with an appropriate conductive, electron-emitting material. The original soluble material is then dissolved following additional metal deposition steps that provide a conductive substrate for the electron emitting material. The method is said to produce up to 10⁶ emitters per cm2, the emitters having a diameter of approximately 1-2 um.

U.S. Pat. No. 5,266,530 describes a gated electron field emitter prepared by a complicated series of deposition and etching steps on a substrate, preferably crystalline.

Carbon, the most important constituent element, which is combined with oxygen, hydrogen, nitrogen and the like, of all organisms including the human body, has four unique crystalline structures including diamond, graphite and carbon. Carbon nano-tubes can function as either a conductor or a semi-conductor according to the constituents of the tube. A conventional approach of fabricating carbon nanotubes is described in an article entitled “epitaxial carbon nanotube film self-organized by sublimation decomposition of silicon carbide” (Appl. Phys. Lett. Vol. 77, pp. 2620, 1997), by Michiko Kusunoky. In the conventional approach, the carbon nanotubes are produced at high temperatures by irradiating a laser onto a graphite silicon carbide. In this particular approach, the carbon nanotubes are produced from graphite at about 1200° C. or more and for silicon carbide at a temperature range of about 1600° C. to 1700° C. However, this method requires a multi-stage approach of deposition of the carbon material. This method is, from a manufacturing perspective, costly and cumbersome.

Another conventional approach is to grow the carbon nanotubes on a silicon substrate. This approach requires that the carbon nanotube material be deposited at temperature higher than 700° C. to ensure a purified and defect-free vertically aligned carbon nanotube structure.

Any attempt to grow the carbon nanotube structure at temperatures below 700° C. results in a defective structure. This conventional approach also results in the inability to control the height of the carbon structure.

FIG. 1 is an illustration of a prior art carbon nanotube structure. The carbon nanotube structure shown in FIG. 1 comprises a silicon film substrate 11 with a catalyst metal layer 13 upon which carbon nanotube layer 15 is deposited. The catalyst layer 13 diffuses into the silicon layer 11 during the growing of the carbon nanotube layer 13. This results in a metal-induction crystallized polysilicon layer 14. The carbon nanotube layer 15 is grown by a plasma deposition and etching method at temperatures ranging from 700° C. to 1700° C. The plasma density in this approach ranges from a high density of 10¹¹ cm³ or more. In the structure in FIG. 1, the diffusion of the catalyst layer 13 into the silicon layer 11 results in a high amount of carbon material being deposited to form the nanotube structure.

FIG. 2 is another prior art structure in which the carbon nanotube is grown at a temperature lower than 700° C. In the structure shown in FIG. 2, the carbon nanotube formed is defective and it is difficult to control the height of the structure resulting in a “spaghetti” like structure being formed. The resulting structure of the carbon nanotube in FIG. 2 is due to the insufficient surface temperature characteristics of the silicon substrate at lower temperatures, the lower driving energy to grow the nanotubes and the dramatic growth of the nanotubes at a lower temperature within a short period of time.

### GENERAL DISCLOSURE OF THE INVENTION

The present invention furnishes an electron-emitting device having a granulized catalyst layer patterned to meet enable the growth and curing of carbon nanotube structures on glass substrates at temperatures lower than 700° C. The present granulized catalyst layer contains multiple laterally separated sections situated between electron emitting carbon nanotube, on one hand, and underlying emitter electrodes, on the other hand. The sections of the catalyst layer are spaced apart along each emitter electrode.

The catalyst sections underlie control electrodes of the present electron-emitting device in various ways. In one general embodiment, the catalyst sections are basically configured as strips situated below the carbon nanotubes. Each granular of catalyst strip is sufficiently long to extend over at least two, typically all, of the emitter electrodes.

In another general embodiment of the granular catalyst layers are formed on a glass substrate and the carbon nanotubes are formed on the catalyst layer at a temperature of about 600° Conductive layer. An anti-diffusion barrier layer is also interlaced between the granular catalyst layer and other layers including a resistive layer in order to ensure a defect free carbon nanotube formation.

Embodiment of the carbon nanotubes structure of the present invention use a plasma chemical vapor deposition system for the dissociation of hydrocarbon gas at a temperature range of 200° C. to 600° C. to grow the carbon nanotube structures. A post growth treatment of the carbon nanotube structure is further performed to control the height of the structures in a microwave plasma chemical vapor deposition environment to ensure a defect free structure.

### BRIEF DESCRIPTION OF THE DRAWINGS

FIG. 1 is a cross-sectional view of the core of a conventional carbon nanotube device.

FIG. 2 is a cross-sectional structural view of a conventional carbon nanotube structure formed at a lower temperature range.

FIG. 3 is cross-sectional view of the core of a carbon nanotube device in accordance with the present invention.

FIGS. 4a-4g are cross-sectional structural views representing steps in manufacturing an embodiment of the carbon nanotube device of FIG. 3 according to the invention.

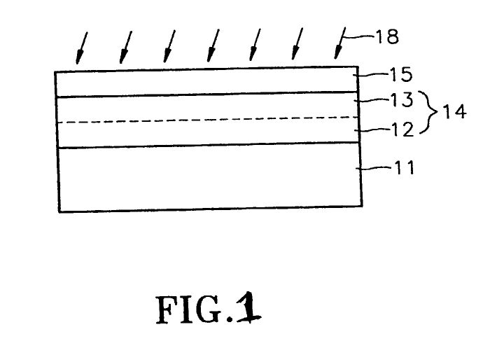

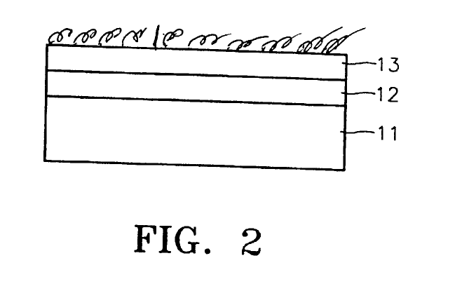

Like reference symbols are employed in the drawings and in the description of the preferred embodiments to represent the same, or very similar, item or items.

### DESCRIPTION OF THE PREFERRED EMBODIMENTS

In the present invention, a vertical conductor connected in series with electron-emissive elements of an electron-emitting device is patterned into multiple sections laterally separated along each emitter electrode in the device. The electron emitter of the invention typically operates according to field-emission principles in producing electrons that cause visible light to be emitted from corresponding light-emissive phosphor elements of a light-emitting device. The combination of the electron-emitting device, often referred to as a field emitter, and the light-emitting device forms a cathode-ray tube of a flat-panel display such as a flat-panel television or a flat-panel video monitor for a personal computer, a lap-top computer, or a workstation.

In the following description, the term “electrically insulating” (or “dielectric”) generally applies to materials having a resistivity greater than 10¹⁰ ohm-cm. The term “electrically non-insulating” thus refers to materials having a resistivity below 10¹⁰ ohm-cm. Electrically non-insulating materials are divided into (a) electrically conductive materials for which the resistivity is less than 1 ohm-cm and (b) electrically resistive materials for which the resistivity is in the range of 1 ohm-cm to 10¹⁰ ohm-cm. These categories are determined at an electric field of no more than 1 volt/μm.

Examples of electrically conductive materials (or electrical conductors) are metals, metal-semiconductor compounds (such as metal suicides), and metal-semiconductor eutectics. Electrically conductive materials also include semiconductors doped (n-type or p-type) to a moderate or high level. The semiconductors may be of the monocrystalline, multicrystalline, polycrystalline, or amorphous type.

Electrically resistive materials include (a) metal-insulator composites such as cermet, (b) certain silicon-carbon compounds such as silicon carbide and silicon-carbon-nitrogen, (c) forms of carbon such as graphite, amorphous carbon, and modified (e.g., doped or laser-modified) diamond, and (d) semiconductor-ceramic composites. Further examples of electrically resistive materials are intrinsic and lightly doped (n-type or p-type) semiconductors.

As used below, an upright trapezoid is a trapezoid whose base (a) extends perpendicular to the direction taken as the vertical, (b) extends parallel to the top side, and (c) is longer than the top side. A transverse profile is a vertical cross section through a plane perpendicular to the length of an elongated region. The row direction in a matrix-addressed field emitter for a flat-panel display is the direction in which the rows of picture elements (pixels) extend. The column direction is the direction in which the columns of pixels extend and runs perpendicular to the row direction.

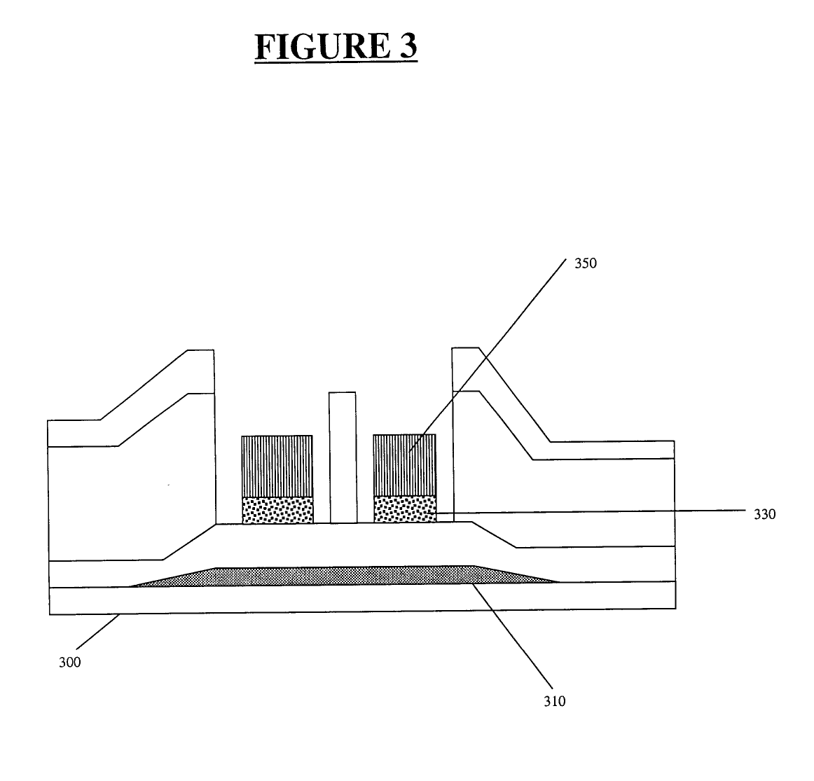

FIG. 3 illustrates the core of a matrix-addressed field emitter that contains a vertical emitter conductor patterned into conductor strips in a vertically aligned manner according to the invention. The cross sections of FIG. 3 is taken through perpendicular planes. The field emitter of FIG. 3 is created from a flat electrically insulating baseplate (substrate) 300 typically consisting of glass having a thickness of approximately 1 mm. To simplify the pictorial illustration, baseplate 300 is not shown in the perspective view of FIG. 3.

A group of generally parallel emitter electrodes 310 are situated on baseplate 300. Emitter electrodes 310 extend in the row direction and constitute row electrodes. Each emitter electrode 310 has a transverse profile roughly in the shape of an upright isosceles trapezoid. This profile helps improve step coverage of layers formed above emitter electrodes 310. A buffer layer 330 is disposed on the emitter electrode 310 to serve as a buffer between the carbon nanotube emission elements 350 and an underlying resistor layer 320. In one embodiment of the present invention, the carbon nanotube emission elements 350 are grown at a temperature range of 200° C. to 600° C. suitable for the thermal stress of the substrate 300.

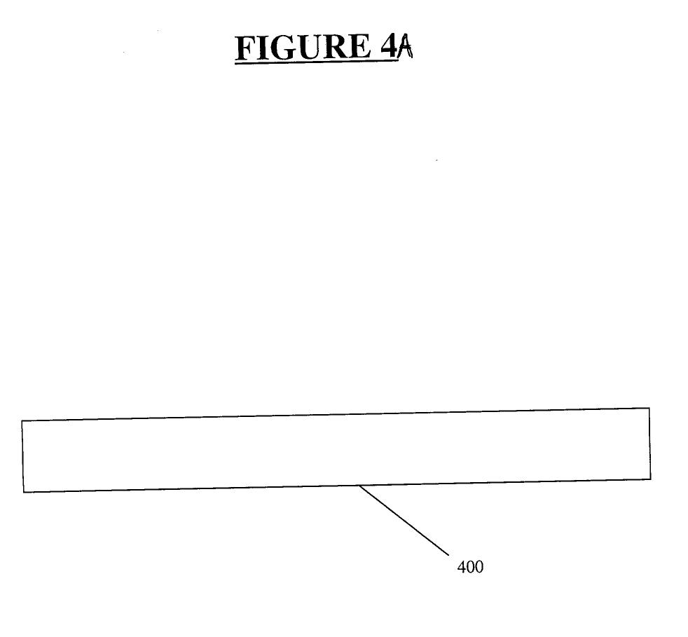

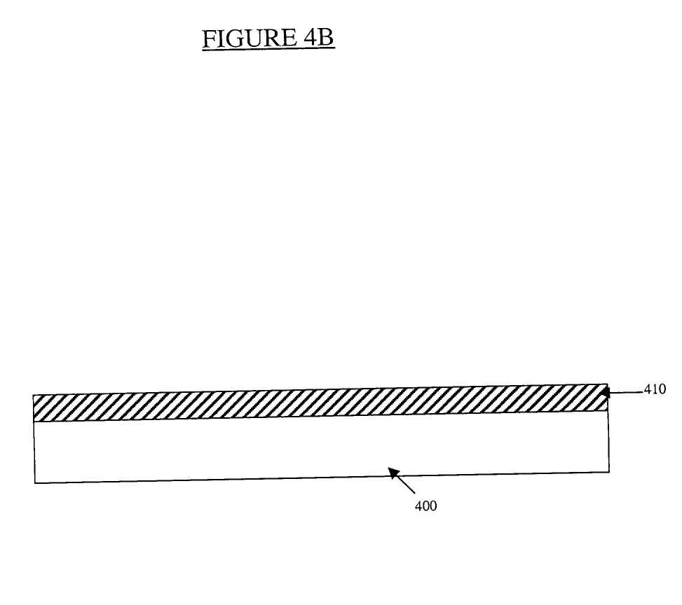

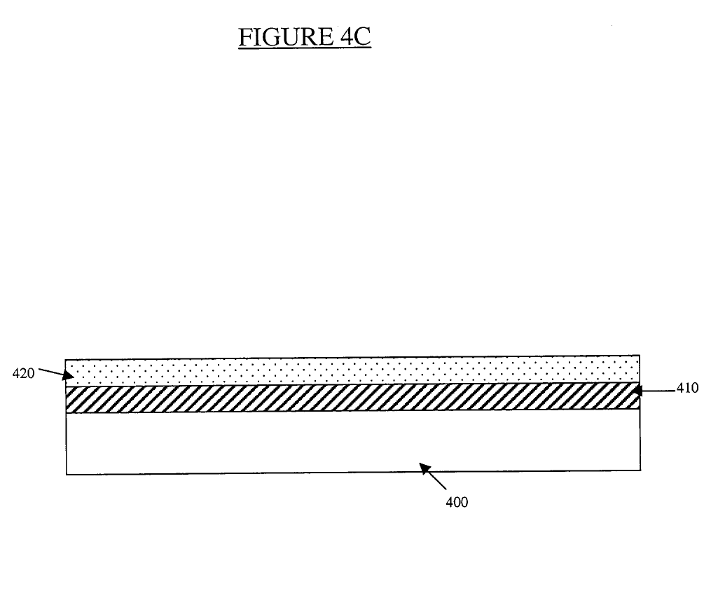

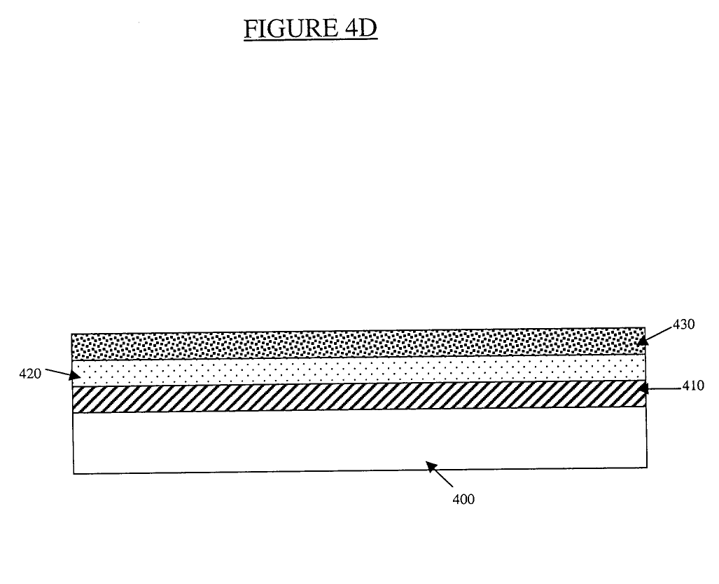

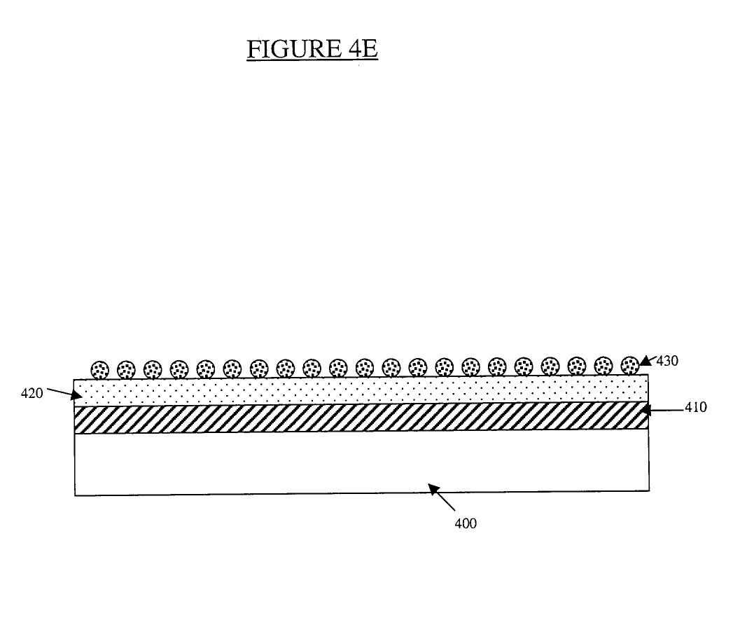

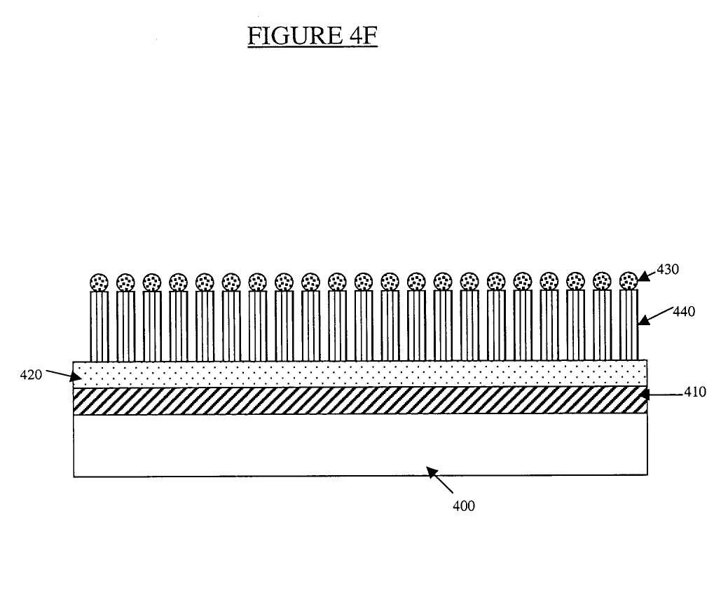

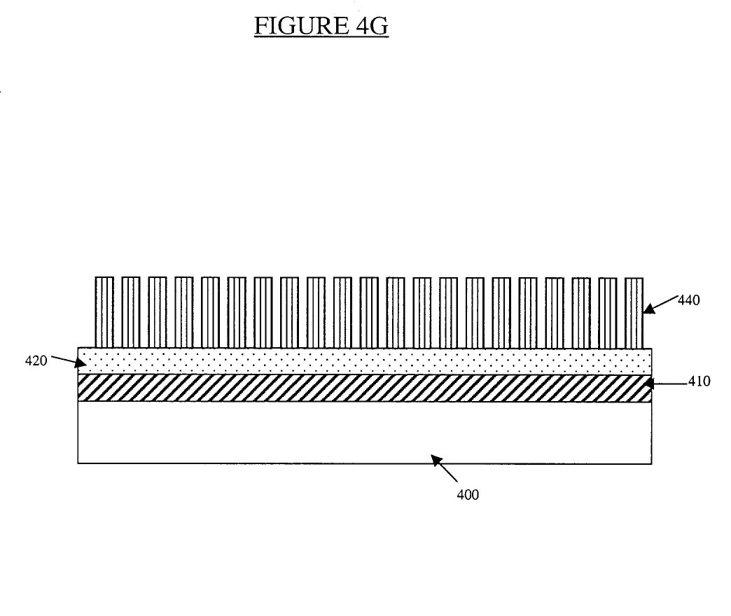

Referring to FIGS. 4A-4G, a substrate for use in the formation of the carbon nanotubes according to an embodiment of the present invention is shown. An emitter electrode 410 is formed on the substrate 400. In the preferred embodiment of the present invention, the substrate 400 is glass. In one embodiment of the present invention, the substrate 400 is ceramic or quartz.

A buffer layer 420 is subsequently disposed on the emitter electrode 410. The buffer layer serves as an anti-diffusion layer for the catalyst layer upon which the carbon nanotubes are formed. In one embodiment of the present invention, the buffer layer 420 may be formed of a metal. In one embodiment, the metal may be molybdenum. In another embodiment, the metal may be titanium or titanium tungsten. In one embodiment of the present invention, the buffer layer 420 may be an alloy of titanium, titanium tungsten, tungsten or molybdenum.

A catalyst layer 430 is subsequently formed over the buffer layer 420. In one embodiment of the present invention, the catalyst layer 430 is formed by a sputtering deposition process. In one embodiment of the present invention, the catalyst layer 430 is deposited to a thickness of about 1 nm to 100 nm.

After deposition of the catalyst layer 430, the substrate 400 is placed in a plasma chamber (not shown). The substrate 400 is then heated to a temperature range of about 200° C. to 600° C. In the one embodiment of the present invention, a capacitively coupled plasma chamber capable of generating a high-density plasma is used. The source gas of deposition plasma may be a hydrogen containing gas. In an alternative embodiment of the present invention, the plasma source may be an inductively coupled plasma.

In one embodiment the hydrogen containing gas may be H₂, NH₃ or H₂+NH₃. In the present invention, the temperature of the substrate is maintained at between 200° C. to 600° C. and the gas density is maintained at 10¹⁰ cm⁻³. The catalyst layer 430 is then treated and granularized into nano size particles as shown in FIG. 4D.

In the granulation phase, the substrate is exposed to granulation gas to patterned the catalyst layer to nano particles. In this phase, the catalyst layer is granularised into multiple round shapes and randomly spread over the buffer layer 420. Having round shaped nano particles enhances the density of carbon nanotube formed on each catalyst particle.

In one embodiment of the present invention, the granule size of the catalyst particles may range from 1 nm to 200 nm. In one embodiment, the granule density may be in the range of 10⁸ cm² to 10¹¹ cm². In one embodiment of the present invention, during the granulation phase, the reaction surface of the catalyst layer 430 is increased to a three dimensional surface through the round shape catalyst particles. The three dimensional surface of the catalyst particles enhances the growing of the carbon nanotubes. The three dimensional surface of the catalyst particles also helps in the diffusion of the carbon nanotubes to the catalyst layer 430. This helps reduce the temperature at which the carbon nanotubes may be formed.

After the granulation phase, the plasma chamber is purged with nitrogen (N₂) gas or argon (Ar) gas and evacuated. In one embodiment of the present invention, Helium (He) may be used to purge the plasma chamber. The substrate 400 is then placed in the chamber and heated to a temperature of about 400° C. to 600° C.

After the granulization of the catalyst layer 430, the carbon nanotubes 440 are grown as illustrated in FIG. 4F. During the growing of the carbon nanotubes 440, a hydrocarbon series gas may be used as a plasma source with NH₃ or H₂ additive gas.

In one embodiment of the present invention, the plasma source gas for growing the carbon nanotubes 440 may be one of CH₄ and C2H₂. The additive gas NH3 or H2 is added to prevent contamination of the carbon naotubes 440. The temperature range of the substrate 400 during the growing of the carbon nanotubes 440 ranges between 200° C. to 600° C. and the plasma gas pressure ranges between 500 to 5000 mTorr. In one embodiment of the present invention, a negative voltage bias is applied to the substrate 400 to improve the vertical growth of the carbon nanotubes 440. In one embodiment of the negative voltage bias is about 50 to 600 volts. The angle of growing the carbon nanotubes 440 to the nominal axis of the substrate 400 is also at an angle lower than 45°. After the carbon nanotubes 400 are grown, the granular particles of the catalyst layer 430 are removed at FIG. 4G.

We claim:

1. A method of forming carbon nanotubes in a flat panel display device comprising:
granulizing a catalyst layer to provide a voluminous surface area for growing a plurality of carbon nanotubes;
heating a substrate upon which said plurality of carbon nanotubes is disposed to a temperature of about 200° C. to 600° C.;
growing said plurality of carbon nanotubes by exposing said substrate to a plasma source gas at a density of 10¹⁰ cm³.

2. The method of claim 1 wherein the plasma source gas is a hydro containing gas.

3. The method of claim 2, wherein said granules of said catalyst layer diffuses into said plurality of carbon nanotubes as said plurality of carbon nanotubes are formed.

4. The method of claim 3, wherein said granules of catalyst layer ranges from 5 Å to 1000 Å in size.

5. The method of claim 4, wherein said plurality of carbon nanotubes are formed on said granules of catalyst layer using a plasma chemical vapor desposition process at a high plasma pressure of 10 mTorr to 5000 mTorr.

6. The method of claim 5, wherein said plasma source gas comprises CH₄.

7. The method of claim 6, wherein said plasma source gas comprises C₂H₂.

8. The method of claim 7, wherein said plasma source gas comprises a mixture of NH₃ and H₂.

9. The method of claim 8, wherein said plasma source gas includes an additive gas to prevent the contamination of said plurality of carbon nanotubes.

10. The method of claim 9, wherein said plasma source comprises a microwave plasma.

11. The method of claim 10, wherein said plasma source comprises an inductively coupled plasma source.

12. The method of claim 11, wherein said plasma source comprises a capacitively coupled plasma sources.

13. The method of claim 12, wherein said additive gas comprises NH₃.

14. The method of claim 13, wherein said additive gas comprises H₂.

15. The method of claim 1, wherein said substrate is glass.
